(19) United States
(12) Patent Application Publication
(10) Pub. No.: US 2012/0313070 A1
(43) Pub. Date: Dec. 13, 2012

(54) CONTROLLED SWITCHING MEMRISTOR

(76) Inventors: R. Stanley Williams, Portola Valley, CA (US); Gilberto Medeiros Ribeiro, Menlo Park, CA (US); Dmitri Borisovich Strukov, Mountain View, CA (US); Jianhua Yang, Palo Alto, CA (US)

(21) Appl. No.: 13/383,597

(22) PCT Filed: Jan. 29, 2010
(86) PCT No.: PCT/US10/22636

§ 371 Date: Jan. 12, 2012

(51) Int. Cl. H01L 45/00; H01L 21/02

(52) U.S. Cl. 257/4; 438/382; 257/E45.002; 257/E21.002

(57) ABSTRACT

A controlled switching memristor includes a first electrode, a second electrode, and a switching layer positioned between the first electrode and the second electrode. The switching layer includes a material to switch between an ON state and an OFF state, in which at least one of the first electrode, the second electrode, and the switching layer is to generate a permanent field within the memristor to enable a speed and an energy of switching from the ON state to the OFF state to be substantially symmetric to a speed and energy of switching from the OFF state to the ON state.

### GOVERNMENT LICENSE RIGHTS

This invention was made in the course of research partially supported by grants from the U.S. Government. The U.S. Government has certain rights in the invention.

### BACKGROUND

Researchers have designed nano-scale reversible switches with an ON-to-OFF conductance ratio of 10⁴. Crossbar circuitry is often constructed using these switches. A useful configuration of this crossbar circuitry is a latch, which is an important component for constructing logic circuits and communicating between logic and memory. Researchers have described logic families entirely constructed from crossbar arrays of switches, as well as hybrid structures using switches and transistors. The application of such components to CMOS circuits has been found to increase the computing efficiency and performance of CMOS circuits.

A potential problem with thin-film semiconductor memristors, which are constructed using the nano-scale reversible switches, for which the active region of the memristors is a uniform dielectric film, is that the speed and energy for switching the memristors ON and OFF differs greatly. This difference may be seen in the plots 10 depicted in FIG. 1, which has been taken from the article by Matthew D. Pickett, et al., entitled “Switching Dynamics in a Titanium Dioxide Memristive Device”, published on Oct. 9, 2009, the disclosure of which is incorporated by reference herein in its entirety.

The plots 10 in FIG. 1 show the time and energy required to turn a titanium dioxide memristive device with a 100 nm diameter from its ON state to its OFF (left two panels, labeled “c” and “e”) and from an OFF state to the ON state (right two panels, labeled “d” and “f”), as a function of the current driven through the device. As shown in the plots 10, current levels of about one order of magnitude larger are required to turn the device OFF compared to turning the device ON within comparable lengths of time. More particularly, for instance, to turn OFF the device in 10 nsec, the energy required is approximate 5×10^{×11} J, whereas to turn ON the device in 10 nsec, the energy required is approximately 2×10⁻¹² J. As such, there is approximately a factor of 20 difference between the ON to OFF switching event as compared with the OFF to ON switching event. Note that because of the decreasing exponential dependence of switching time on current, the switching energy actually decreases for increasing current. Thus, if the amount of energy for switching the device ON and OFF is fixed, switching OFF the device will require a significantly longer length of time than switching ON the device.

The difference in the levels of energy occurs because for ON to OFF-switching, mobile charged dopants are being pushed from an initial configuration in which they are more uniformly distributed across the thin film to one in which they are more concentrated on one side of the device and less concentrated on the other. This nonuniform distribution of the dopants has two effects—one is that there is a significant Fickian diffusive force acting opposite to the force of the applied field and the other is that an internal field builds up to oppose the applied field. These effects acting together slow down the drift of the mobile dopants, thus making the switching speed slower and the energy required to move the dopants larger. For OFF to ON-switching, the external bias, the internal field and the diffusive forces are all acting in the same direction, so that the switching event is significantly more rapid and requires an order of magnitude less energy.

### BRIEF DESCRIPTION OF THE DRAWINGS

Embodiments are illustrated by way of example and not limited in the following figure(s), in which like numerals indicate like elements, in which:

FIG. 1 illustrates plots of the time and energy required to turn a conventional titanium dioxide memristive device from its ON state to its OFF state and from an OFF state to an ON state;

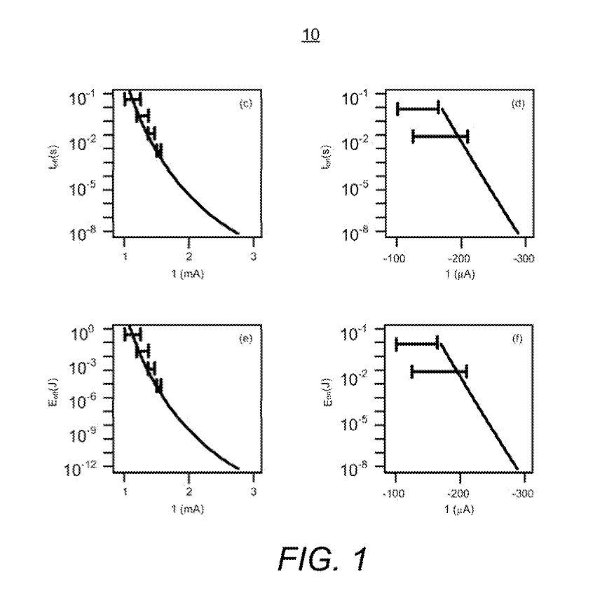

FIG. 2A illustrates a perspective view of a portion of an electrically actuated device or memristor, according to an embodiment of the invention;

FIG. 2B illustrates a crossbar array employing a plurality of the electrically actuated devices or memristors depicted in FIG. 2A, according to an embodiment of the invention;

FIGS. 3A-3D, respectively illustrate band diagrams for an ionic electronic conductor with a bulk chemical potential in proximity with an electrode with different metal work functions, according to embodiments of the invention; and

FIG. 4 illustrates a flow diagram of a method of fabricating an electrically actuated switch or memristor, according to an embodiment of the invention.

### DETAILED DESCRIPTION

For simplicity and illustrative purposes, the principles of the embodiments are described by referring mainly to examples thereof. In the following description, numerous specific details are set forth in order to provide a thorough understanding of the embodiments. It will be apparent however, to one of ordinary skill in the art, that the embodiments may be practiced without limitation to these specific details. In other instances, well known methods and structures are not described in detail so as not to unnecessarily obscure the description of the embodiments.

Disclosed herein is an electrically actuated device, which is equivalently recited herein as a memristor, composed of electrodes spaced apart from each other by a switching layer. It should thus be understood that the terms “electrically actuated device” and “memristor” are used interchangeably throughout the present disclosure. In any regard, the switching layer comprises transition metal oxides, which may be found in conventional memristor device, and are configured to be in an electrically insulating (OFF) state or an electrically conductive state (ON) state. As discussed in greater detail herein below, one or both of the electrodes and/or the switching layer is configured so as to build up a permanent internal field within the electrically actuated device to substantially balance the switching speeds and energies for the switching polarities. In addition, the permanent internal field may be built up while maintaining other desirable characteristics, such as, lower power operation and current rectification at both of the electrodes of the electrically actuated device.

Through implementation of the electrically actuated device disclosed herein, the switching characteristics of the electrically actuated device may be controlled. For instance, the switching characteristics may be controlled such that the amount of energy and speed required to turn ON the device may be substantially symmetric with the amount of energy and speed required to turn OFF the device.

Micron-scale dimensions refer to dimensions that range from 1 micrometer to a few micrometers in size.

For the purposes of this application, nanometer scale dimensions refer to dimensions ranging from 1 to 50 nanometers.

A crossbar is an array of switches that can connect each wire in one set of parallel wires to every member of a second set of parallel wires that intersects the first set (usually the two sets of wires are perpendicular to each other, but this is not a necessary condition).

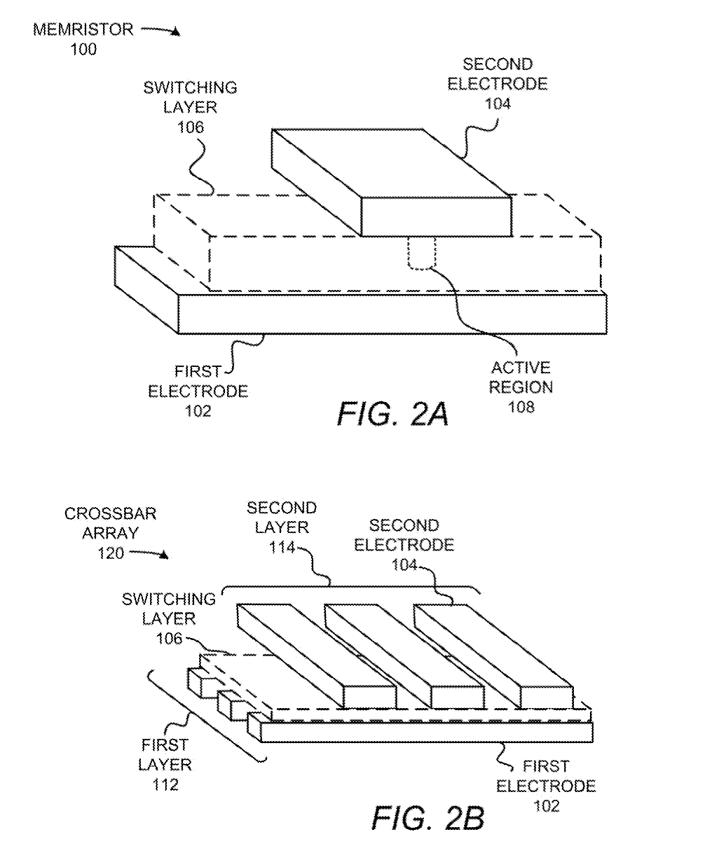

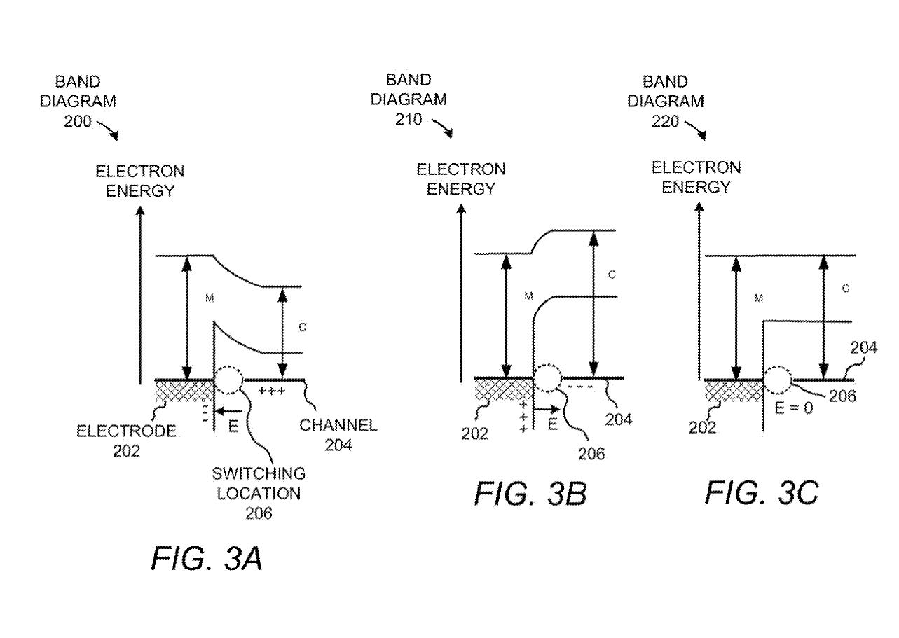

With reference first to FIG. 2A, there is shown a perspective view of a portion of a controlled switching electrically actuated device or memristor 100, according to an embodiment. It should be understood that the electrically actuated device 100 depicted in FIG. 2A may include additional components and that some of the components described herein may be removed and/or modified without departing from a scope of the electrically actuated switch 100. It should also be understood that the components depicted in FIG. 2A are not drawn to scale and thus, the components may have different relative sizes with respect to each other than as shown therein. Thus, for instance, the switching layer 106 may be significantly smaller or larger than the first and second electrodes 102 and 104 as compared with their relative sizes shown in FIG. 2A.

As depicted in FIG. 2A, the electrically actuated device 100 includes a first electrode 102, a second electrode 104, and a switching layer 106 positioned between the first electrode 102 and the second electrode 104. In addition, the first electrode 102 is depicted as being in a relatively crossed arrangement with respect to the second electrode 104. The location where the first electrode 102 crosses the second electrode 104 and where a change in the electrical behavior of the switching layer 106 occurs is labeled as an active region 108. The active region 108 may be considered to be the area that becomes electrically conductive during an electroforming process, as described in greater detail herein below.

In addition, the switching layer 106 has been shown with dashed lines to generally indicate that the switching layer 106 extends beyond the first and second electrodes 102 and 104. In other embodiments, however, the switching layer 106 may be formed of relatively smaller sections of material positioned where the first electrode 102 crosses the second electrode 104.

The electrically actuated device 100 may be built at the micro- or nano-scale and used as a component in a wide variety of electronic circuits, such as, bases for memories and logic circuits. When used as a basis for memories, the device 100 may be used to store a bit of information, 1 or 0. When used as a logic circuit, the device 100 may be employed to represent bits in a Field Programmable Gate Array, or as the basis for a wired-logic Programmable Logic Array. The electrically actuated device 100 disclosed herein is also configured to find uses in a wide variety of other applications.

With reference now to FIG. 2B, there is shown a crossbar array 120 employing a plurality of the electrically actuated devices 100 shown in FIG. 2A, according to an embodiment. It should be understood that the crossbar array 120 depicted in FIG. 2B may include additional components and that some of the components described herein may be removed and/or modified without departing from a scope of the crossbar array 120.

As shown in FIG. 2B, a first layer 112 of approximately parallel first electrodes 102 is overlain by a second layer 114 of approximately parallel second electrodes 104. The second layer 114 is roughly perpendicular, in orientation, to the first electrodes 102 of the first layer 112, although the orientation angle between the layers may vary. The two layers 112, 114 form a lattice, or crossbar, with each second electrode 104 of the second layer 114 overlying all of the first electrodes 102 of the first layer 112 and coming into close contact with each first electrode 102 of the first layer 112 at respective junctions 106, which represent the closest contact between two of the first and second electrodes 102 and 104. The crossbar array 120 depicted in FIG. 2B may be fabricated from micron-, submicron or nanoscale-electrodes 102, 104, depending on the application.

Although the first electrodes 102 and second electrodes 104 depicted in FIGS. 2A and 2B are shown with square or rectangular cross-sections, the second electrodes 104 may have circular, hexagonal, or more complex cross-sections, such as, triangular cross-sections. The electrodes 102, 104 may also have many different widths or diameters and aspect ratios or eccentricities. The term “nanowire crossbar” may refer to crossbars having one or more layers of sub-microscale electrodes, microscale electrodes or electrodes with larger dimensions, in addition to nanowires.

In both FIGS. 2A and 2B, the switching layer 106 is composed of a material that is switched between a generally insulating (OFF) state and a generally conductive (ON) state by migration of oxygen vacancies. The migration of oxygen vacancies in the switching layer 106 may occur, for instance, through the bias of a voltage applied through the switching layer 106 across the first electrode 102 and the second electrode 104. In this regard, the switching layer 106 is composed of a switching material, such as a material formed of a molecule having a switchable segment or moiety that is relatively energetically stable in two different states. The switching material may include any suitable material known to exhibit these properties. By way of particular example the switching layer 106 is composed of titanium dioxide (TiO₂) or other oxide species, such as nickel oxide or zinc oxide, etc.

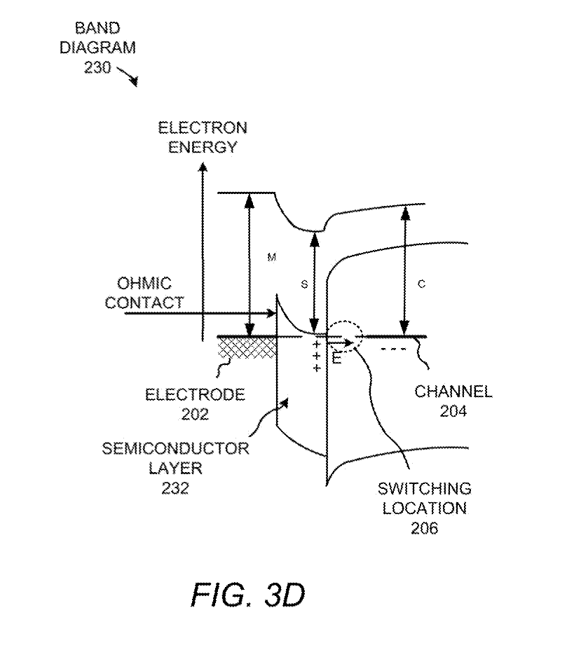

As discussed above in the Background section, the amount of time required to change the switching layer 106, and more particularly, the active region 108, from an ON state to an OFF state differs greatly from the amount of time required to change the active region 108 from the OFF state to the ON state, if the energy levels for both switching operations are the same. These differences may occur due to differences in the work functions (φ_{M}) of the metals used in the electrodes 102 and 104 and the bulk chemical potential (μ_{C}) of the switching layer 106. The work functions (φ_{M}) of the metals may generally be defined as the amount of energy required to extract one electron from the metal and to put the electron into a vacuum. These differences are graphically illustrated in FIGS. 3A-3D, which respectively depict band diagrams 200, 210, 220, and 230.

FIGS. 3A-3D, more particularly, depict examples of band diagrams for an (metal oxide) ionic electronic conductor with a bulk chemical potential (μ_{C}) in proximity with an electrode 202 with different metal work functions (φ_{M}) according to embodiments of the invention. The electrode 202 may comprise one of the electrodes 102 and 104 discussed above. In addition, the channels 204 are the metallic channels or highly doped regions in the switching layer 106 that are formed during the electroforming process discussed above. Moreover, the gap between the electrode 202 and the channel 204 denotes a switching location 206 in the device 100 where switching occurs. For instance, positively charged ions will move into the switching location 206 under applied fields to change the device 100 between the ON and OFF states.

With reference first to FIG. 3A, the selected electrode 202 and channel 204 results in a bulk chemical potential (μ_{C}) that is higher in energy than the metal work function (φ_{M}) of the electrode 202. This difference causes electrons to flow toward the electrode 202. As such, the electrode 202 is negatively charged and the channel 204 is positively charged. In this situation, the internal field in the device 100 would make ON switching faster than the OFF switching if mobile ions have a positive electric charge.

With reference now to FIG. 3B, the selected electrode 202 and channel 204 results in a bulk chemical potential (μ_{C}) that is higher in energy than the metal work function (φ_{M}) of the electrode 202. This difference causes electrons to flow toward the channel 204. As such, the electrode 202 is positively charged and the channel 204 is negatively charged. In this situation, the internal field in the device 100 would make OFF switching faster than the ON switching if mobile ions have a positive electric charge.

With reference now to FIG. 3C, the selected electrode 202 and channel 204 results in a bulk chemical potential (μ_{C}) that is substantially equivalent to the metal work function (φ_{M}) of the electrode 202. This equivalence results in a substantial balance in charges between the electrode 202 and the channel 204. In this situation, OFF switching and ON switching rates are substantially similar. In addition, the substantial balance in charges may assist in getting smoother ON switching if there are any interface dipoles present in the device 100.

With reference now to FIG. 3D, there is shown an example of a band diagram 230 in which an additional heavily donor doped semiconductor layer 232 (blocking for mobile ions) with a bulk chemical potential (φ_{S}) and an Ohmic contact to the electrode introduced between the conducting channel and the electrode. The addition of the semiconductor layer 232 having the bulk chemical potential (φ_{S}) between the electrode 202 and the channel 204 and the Ohmic contact to the electrode 202 effectively reduces the work function of the electrode 202, which may circumvent potential problems with low work function electrodes, such that the field direction in the switching location 206 is similar to the field direction shown in FIG. 3B. In other words, when the electrode 202 has a relatively high work function, a semiconductor layer 232 having a relatively lower bulk chemical potential (φ_{S}) may be placed between the electrode 202 and the channel 204 to reduce the electrical conductivity between the electrode 202 and the channel 204.

Generally speaking, at least one of the first electrode 102, the second electrode 104, and the switching layer 106 is configured to generate a permanent field within the electrically actuated device 100 to enable a speed and an energy of switching from the ON state to the OFF state to be substantially symmetric to a speed and energy of switching from the OFF state to the ON state. More particularly, for instance, at least one of the first electrode 102, the second electrode 104, and the switching layer 106 is configured to cause the electrical field between an electrode 202 and a channel 204 formed in the switching layer 106 to be substantially balanced in the switching location 206 as shown in FIG. 3C.

According to an embodiment, the permanent field within the electrically actuated device 100 is generated by selecting metals or metal compounds having different work-functions for the first electrode 102 and the second electrode 104. In this embodiment, for instance, the first electrode 102 may be formed of a metal having a substantially high work-function, such as, platinum (Pt), gold (Au), cobalt (Co), osmium (Os), palladium (Pd), nickel (Ni), and the like. In addition, the second electrode 104 may be formed of a metal having a substantially low work-function, such as, silver (Ag), aluminum (Al), barium (Ba), europium (Eu), gadolinium (Gd), lanthanum (La), magnesium (Mg), neodymium (Nd), scandium (Sc), vanadium (V), and yttrium (Y). The second electrode 104 may also be formed of metallic compound contacts, such as, TiNx, HfCx, and the like.

In this embodiment, for instance, a metal having a work function that substantially negates the bulk chemical potential of the channel 204 may be selected as one or both of the electrodes 102 and 104. Thus, by way of particular example in which the electrically actuated device 100 comprises a band diagram 200 similar to that shown in FIG. 3A, the electrode 202 may be replaced with another electrode having a lower work function to thereby bring the electrical field in the switching location 206 closer to symmetry as shown in FIG. 3C.

According to another embodiment, the permanent field within the electrically actuated device 100 is generated by co-doping the switching layer 106 with one of immobile acceptors and donors to create a potential gradient in the switching layer 106. Examples of suitable immobile acceptors are carbon (C), nitrogen (N), and a number of various trivalent, divalent, and monovalent metals. Particular examples of the immobile acceptors include nickel (Ni), Sc, La, etc. Examples of suitable immobile donors are the pentavalent, hexavalent, and heptavalent transition metals, such as, vanadium (V), niobium (Nb), tantalum (Ta), chromium (Cr), molybdenum (Mo), tungsten (W), manganese (Mn), rhenium (Re), and the like.

In this embodiment, for instance, a switching material 106 within which a channel 204 having a bulk chemical potential that substantially negates the work function of the electrode 202 may be selected. Thus, by way of particular example in which the electrically actuated device 100 comprises a band diagram 200 similar to that shown in FIG. 3B, the switching material 106 may be replaced with another switching material 106 having a lower bulk chemical potential to thereby bring the electrical field in the switching location 206 closer to symmetry as shown in FIG. 3C.

According to a further embodiment, the permanent field within the electrically actuated device 100 is generated by forming the switching layer 106 as a heterostructure configured to generate an internal potential in the switching layer 106. More particularly, the heterostructures comprise semiconductor heterostructures that are used to create potential wells that help to stabilize or destabilize the position of charged dopants. For instance, the switching layer 106 is formed of a first layer having a stoichiometric oxide and a second layer having an oxygen deficient oxide.

A number of different types of band-offset alignments are possible with the present embodiment. In general, a semiconductor or insulator with a larger band-gap will be attractive for dopants and one with a smaller band-gap will be repulsive, however, the actual situation depends on the details of how the conduction and valence bands actually line up with each other in the heterostructure and how much chemical interaction there may be at the interfaces of the materials. According to a particular example in which one of the materials of the heterostructure comprises TiO₂, examples of materials with larger band gaps are ZrO₂, HfO₂, MgO, GeO₂, Al₂O₃, CaO, etc., and examples of materials with smaller band gaps are the binary oxides of V, Mo, W, Ce, Fe, Co, Ni, Ti, Zn, Pb, etc., as well as various other ternary and higher order compounds.

In this embodiment, for instance, a switching material 106 within which a channel 204 having a heterostructure whose combined bulk chemical potential substantially negates the work function of the electrode 202 may be selected. Thus, by way of particular example in which the electrically actuated device 100 comprises a band diagram 200 similar to that shown in FIG. 3B, the switching material 106 may be replaced with a heterostructure having a combined lower bulk chemical potential to thereby bring the electrical field in the switching location 206 closer to symmetry as shown in FIG. 3C.

According to a further embodiment, various combinations of the previously discussed embodiments may be implemented to generate the permanent field in the electrically actuated device 100.

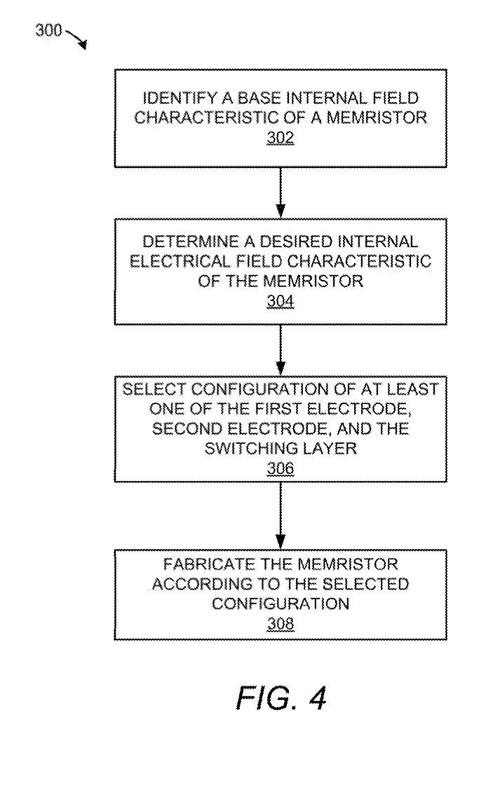

Turning now to FIG. 4, there is shown a flow diagram of a method 300 of fabricating an electrically actuated device or memristor 100, according to an embodiment. It should be understood that the method 300 of fabricating the electrically actuated switch or memristor 100 depicted in FIG. 4 may include additional steps and that some of the steps described herein may be removed and/or modified without departing from a scope of the method 300 of fabricating the electrically actuated switch or memristor 100.

At step 302, a base internal electrical field characteristic of the memristor 100 is identified. Thus, for instance, a determination as to whether a base memristor 100 has electrical field characteristics similar to those depicted in any of FIGS. 3A-3D may be determined.

At step 304, a desired internal electrical field characteristic of the memristor 100 is determined. A desired internal electrical field characteristic may comprise the symmetric electrical field depicted in FIG. 3C.

At step 306, a configuration of at least one of the first electrode, the second electrode, and the switching layer to produce the desired internal electrical field characteristic based upon the base internal field characteristic of the electrically actuated device is selected. As discussed above, there are a number of configurations that are available within the scope of the invention to produce the desired internal electrical and field. In one embodiment, the first electrode is selected to be formed of a relatively highly work-function metal and the second electrode to be formed of a relatively low work-function metal. In another embodiment, a switching layer that is co-doped with one of immobile acceptors and donors to create a potential gradient in the switching layer is selected to generate a permanent field within the electrically actuated switch. In a further embodiment, a switching layer that comprises a heterostructure configured to generate an internal potential in the switching layer is selected. In a yet further embodiment, a combination of the above-discussed embodiments may be employed.

At step 308, the memristor 100 is fabricated according to the configuration selected at step 306. By way of example, the first electrode 102 and the second electrode 104 are formed through any suitable formation process, such as, chemical vapor deposition, sputtering, etching, lithography, etc. In addition, the switching layer 106 may be grown between the first electrode 102 and the second electrode 104.

What has been described and illustrated herein is an embodiment along with some of its variations. The terms, descriptions and figures used herein are set forth by way of illustration only and are not meant as limitations. Those skilled in the art will recognize that many variations are possible within the spirit and scope of the subject matter, which is intended to be defined by the following claims—and their equivalents—in which all terms are meant in their broadest reasonable sense unless otherwise indicated.

1. A controlled switching memristor comprising:
a first electrode;
a second electrode; and
a switching layer positioned between the first electrode and the second electrode, said switching layer comprising a material to switch between an ON state and an OFF state, wherein at least one of the first electrode (102), the second electrode (104), and the switching layer (106) is to generate a permanent field within the memristor (100) to enable a speed and an energy of switching from the ON state to the OFF state to be substantially symmetric to a speed and energy of switching from the OFF state to the ON state.

2. The controlled switching memristor according to claim 1, wherein the first electrode is formed of a relatively high work-function metal and the second electrode is formed of a relatively low work-function metal.

3. The controlled switching memristor according to claim 2, wherein the first electrode is formed of a metal from the group consisting of platinum, gold, cobalt, osmium, palladium, and nickel.

4. The controlled switching memristor according to claim 2, wherein the second electrode is formed of at least one of a metal from the, group consisting of silver, aluminum, barium, europium, gadolinium, lanthanum, magnesium, neodymium, scandium, vanadium, and yttrium and a metallic compound contact.

5. The controlled switching memristor according to claim 1, wherein the switching layer is co-doped with one of immobile acceptors and donors to create a potential gradient in the switching layer to generate a permanent field within the memristor to enable the speed and energy of switching from the ON state to the OFF state to be substantially symmetric to the speed and energy of switching from the OFF state to the ON state.

6. The controlled switching memristor according to claim 5, wherein the immobile acceptors comprise materials from the group consisting of carbon, nitrogen, and a plurality of trivalent, divalent, and monovalent metals.

7. The controlled switching memristor according to claim 5, wherein the immobile donors comprise materials from the group consisting of pentavalent, hexavalent, and heptavalent transition metals.

8. The controlled switching memristor according to claim 1, wherein the switching layer comprises a heterostructure to generate an internal potential in the switching layer.

9. The controlled switching memristor according to claim 8, wherein the switching layer comprises a first layer having a stoichiometric oxide and a second layer having an oxygen deficient oxide.

10. A crossbar array composed of a plurality of memristors, said crossbar array comprising:
a plurality of first electrodes positioned approximately parallel with respect to each other;
a plurality of second electrodes positioned approximately parallel with respect to each other and approximately perpendicularly with the plurality of first electrodes; and
a switching layer is positioned between the plurality of first electrodes and the plurality of second electrodes, said switching layer comprising a material to switch between an ON state and an OFF state, wherein at least one of the plurality of first electrodes, the plurality of second electrodes, and the switching layer is to generate a permanent field within the memristor to enable a speed and an energy of switching from the ON state to the OFF state to be substantially symmetric to a speed and energy of switching from the OFF state to the ON state.

11. A method for fabricating a controlled switching memristor, said method comprising:
identifying a base internal electrical field characteristic of the memristor;
determining a desired internal electrical field characteristic of the memristor; and
selecting a configuration of at least one of a first electrode, a second electrode, and a switching layer to produce the desired internal electrical field characteristic based upon the base internal field characteristic of the memristor, said switching layer comprising a material to switch between an ON state and an OFF state, wherein at least one of the first electrode, the second electrode, and the switching layer is to generate a permanent field within the memristor to enable a speed and an energy of switching from the ON state to the OFF state to be substantially symmetric to a speed and energy of switching from the OFF state to the ON state.

12. The method according to claim 11, wherein selecting the configuration further comprises selecting the first electrode to be formed of a relatively high work-function metal and the second electrode to be formed of a relatively low work-function metal.

13. The method according to claim 11, wherein selecting the configuration further comprises selecting a switching layer that is co-doped with one of immobile acceptors and donors to create a potential gradient in the switching layer to generate a permanent field within the memristor.

14. The method according to claim 11, wherein selecting the configuration further comprises selecting a switching layer that comprises a heterostructure to generate an internal potential in the switching layer.

15. The method according to claim 11, further comprising:
fabricating the memristor by,
providing the selected first electrode;
providing the selected switching layer on the first electrode; and
providing the selected second electrode on the selected switching layer.
